(19) United States
(12) Patent Application Publication
(10) Pub. No.: US 2026/0299004 A1
(43) Pub. Date: Oct. 1, 2026

(54) SEMICONDUCTOR DEVICE DEFECT AND FAULT ISOLATION

(71) Applicant: Intel Corporation, Santa Clara, CA (US)

(72) Inventors: Chandrashekara Shashank KAIRA, Chandler, AZ (US); Denis MYASISHCHEV, Chandler, AZ (US); Deepak GOYAL, Phoenix, AZ (US)

(21) Appl. No.: 19/094,895

(22) Filed: Mar. 29, 2025

(51) Int. Cl. G01R 31/26; G01J 5/00

(52) U.S. Cl. CPC G01R 31/2642; G01J 5/0007; G01J 2005/0077

(57) ABSTRACT

A fault isolation module for detecting electrical defects through DC and/or RF thermal excitation in semiconductor devices is provided. Using a coupled thermal imaging module, thermally excited defects and thermal signatures for defects can be detected.

### FIELD

Descriptions are generally related to testing for semiconductor device manufacturing, and more particular descriptions are related to defect and fault isolation in semiconductor devices.

### BACKGROUND

Semiconductor chips are central to intelligent devices and systems, such as personal computers, laptops, tablets, phones, servers, and other consumer and industrial products and systems. Manufacturing semiconductor chips presents a number of challenges and these challenges are amplified as devices become smaller and performance demands increase. Challenges include, for example, unwanted material interactions, precision and scaling requirements, power delivery requirements, limited failure tolerance, and material and manufacturing costs.

Semiconductor test processes play a key role in manufacturing. Testing is important for both process development and process failure analysis during manufacturing. Continuing progress toward ever smaller and more integrated semiconductor device and device packaging solutions can result in solutions that pose challenges from a yield perspective due to their inherent complexity. For instance, combining different packaging architectures such as, for example, three dimensional die-to-die stacking, multi-die interconnect bridges, three dimensional stacking of memory chips for high bandwidth memory (HBM) and other high bandwidth integrated (HBI) architectures, and omni-directional interconnects (ODI), can allow design flexibility and augment performance through both vertical and horizontal integration to enable heterogeneous compute products. These heterogeneous compute products can allow mixing of silicon components having varied functionality that have been fabricated across multiple process nodes. Semiconductor device testing is a foundational part of the manufacturing processes for ever smaller and more complex semiconductor device architectures.

### BRIEF DESCRIPTION OF THE DRAWINGS

The figures are provided to aid in understanding the disclosure. The figures can include diagrams and illustrations of examples of structures, assemblies, data, methods, and systems. For ease of explanation and understanding, these structures, assemblies, data, methods, and systems, the figures are not an exhaustively detailed description. The figures therefore should not be understood to depict the entire metes and bounds of structures, assemblies, data, methods, and systems possible without departing from the scope of the disclosure. Additionally, features are not necessarily illustrated relatively to scale due in part to the small sizes of some features and the desire for clarity of explanation in the figures.

FIG. 1 provides a system that is useful for electrical testing of semiconductor devices.

FIG. 2 illustrates a fault isolation module that is useful for in a system for electrical testing of semiconductor devices.

FIGS. 3A-3C show operation of a fault isolation module to detect electrical defects and faults.

FIG. 4 provides a method for electrical fault isolation in semiconductor devices.

FIG. 5 provides an example of a computing system.

Descriptions of certain details and implementations follow, including non-limiting descriptions of the figures, which depict some examples and implementations.

### DETAILED DESCRIPTION

References to one or more examples are to be understood as describing a particular feature, structure, or characteristic included in at least one implementation. The phrases “one example” or “an example” are not necessarily all referring to the same example or embodiment. Any aspect described herein can potentially be combined with any other aspect or similar aspect described herein, regardless of whether the aspects are described with respect to the same figure or element.

The words “connected” and/or “coupled” can indicate that two or more elements are in direct physical or electrical contact with each other. The term “coupled,” however, can also mean that two or more elements are not in direct contact with each other and are instead separated by one or more elements but they may still co-operate or interact with each other, for example, physically, magnetically, optically, or electrically.

The words “first,” “second,” and the like, do not indicate order, quantity, or importance, but rather are used to distinguish one element from another. The words “a” and “an” herein do not indicate a limitation of quantity, but rather denote the presence of at least one of the referenced items. The terms “follow” or “after” can indicate immediately following or following some other event or events. Other sequences of operations can also be performed according to alternative embodiments. Furthermore, additional operations may be added or removed depending on the application.

Disjunctive language such as the phrase “at least one of X, Y, or Z,” is used in general to indicate that an element or feature, may be either X, Y, or Z, or any combination thereof (e.g., X, Y, and/or Z). Thus, this disjunctive language should be understood not to imply that certain embodiments require at least one of X, at least one of Y, or at least one of Z to each be present.

Flow diagrams as illustrated herein provide examples of sequences of various process actions. The flow diagrams can indicate operations to be executed by a software or firmware routine, as well as by physical operations. Operations can be performed by semiconductor testing equipment, including computer systems that run testing protocols and operate aspects of testing equipment and systems. Although shown in a particular sequence or order, unless otherwise specified, the order of the actions can be modified. Thus, the illustrated diagrams should be understood as examples. The processes can be performed in a different order, and some actions can be performed in parallel. Additionally, one or more actions can be omitted and not all implementations may necessarily perform all actions.

Various components described can be a means for performing the operations or functions described. Components described can include software, hardware, or a combination of these. Some components can be implemented as software modules, hardware modules, special-purpose hardware (for example, application specific hardware, application specific integrated circuits (ASICs), and digital signal processors (DSPs)), embedded controllers, and/or hardwired circuitry.

To the extent various computer operations or functions are described herein, they can be described or defined as software code, instructions, configuration, and/or data. The software content can be provided via an article of manufacture with the content stored thereon, or via a method of operating a communication interface to send data via the communication interface. A machine-readable storage medium can cause a machine to perform the functions or operations described. A machine-readable storage medium includes any mechanism that stores information in a tangible form accessible by a machine (e.g., computing device), such as recordable/non-recordable media (e.g., read only memory (ROM), random access memory (RAM), magnetic disk storage media, optical storage media, flash memory devices). Instructions can be stored on the machine-readable storage medium in a non-transitory form. A communication interface includes any mechanism that interfaces to, for example, a hardwired, wireless, or optical medium to communicate to another device, such as, for example, a memory bus interface, a processor bus interface, an Internet connection, a disk controller.

Terms such as chip, die, IC (integrated circuit) chip, IC die, microelectronic chip, microelectronic die, semiconductor die, and/or semiconductor chip are interchangeable and refer to a device comprising integrated circuits that can be formed in part from semiconductor materials.

Semiconductor chip manufacturing processes are sometimes divided into front end of the line (FEOL) processes and back end of the line (BEOL) processes. Electronic circuits and active and passive devices within the chip, such as for example, transistors, capacitors, resistors, and/or memory cells, are manufactured in what can be referred to as FEOL processes. Memory cells include, for example, electronic circuits for random access memory (RAM), such as static RAM (sRAM), dynamic RAM (DRAM), read only memory (ROM), non-volatile memory, and/or flash memory. FEOL processes can be, for example, complementary metal-oxide semiconductor (CMOS) processes. BEOL processes include metallization of the chip where interconnects are formed in layers and the feature size of the interconnect increases in layers nearer the surface of the semiconductor chip. Interconnects in, for example, semiconductor chips that are integrated into heterogeneous packages (such as, for example, packages that include memory and logic chips), can also include through silicon vias (TSVs) that transverse the semiconductor chip device region. Semiconductor chips that have TSVs can blur distinctions between BEOL and FEOL processes.

Semiconductor chip interconnects can be created by forming a trench or though-layer via by etching a trench or via structure into a dielectric layer and filling the trench or via with metal. Dielectric layers can comprise, for example, low-K dielectrics, SiO₂, silicon nitride (SiN), silicon carbide (SiC), and/or silicon carbonitride (SiCN). Low-K dielectrics include for example, fluorine-doped SiO₂, carbon-doped SiO₂, porous SiO₂, porous carbon-doped SiO₂, combinations for the foregoing, and also these materials with gas-filled gaps or bubbles. Dielectric layers that include conductive features can be interlayer dielectric (ILD) features. In general, low-K dielectrics exhibit a dielectric constant that is less than that of SiO₂.

The terms “package,” “packaging,” “IC package,” or “chip package,” “microelectronics package,” or “semiconductor chip package” are interchangeable and generally refer to an enclosed carrier of one or more chips, in which the chips are coupled to a package substrate and encapsulated. The package substrate provides electrical interconnections between the chip(s) and other chips and/or a motherboard or other circuit board for I/O (input/output) communication and power delivery. A package with multiple chips can, for example, be a system in a package.

A package substrate generally includes dielectric layers or structures having conductive structures on, through, and/or embedded in the dielectric layers. The dielectric layers can be, for example, build-up layers. Dielectric materials include Ajinomoto build-up film (ABF), although other dielectric materials are possible. Semiconductor package substrates can have cores or be coreless. Semiconductor packages having cores can have dielectric layers such as buildup layers on more than one side of a core, such as on two opposite sides of a core. Cores can include through-core vias that contain a conductive material. Other structures or devices are also possible within a package substrate.

A “core” or “package core” generally refers to a layer usually embedded within a package substrate. The core can provide structure or stiffness to a package substrate. A core is an optional feature of a package substrate. The core can be a dielectric organic or inorganic material and may have conductive vias extending through the layer. The conductive vias can include a metal, for example, copper. A package core can, for example, be comprised of a glass material (such as, for example, aluminosilicate, borosilicate, alumino-borosilicate, silica, and fused silica), silicon, silicon nitride, silicon carbide, gallium nitride, or aluminum oxide. In some examples, core materials are glass-fiber reinforced organic resins such as epoxy-based resins. A further example package substrate core is FR4 (woven glass fiber reinforces epoxy). In other examples, package substrate cores are solid amorphous glass layers.

In further examples of a package substrate core, the substrate core is a glass core comprising one or more solid amorphous glass layers. The glass substrate core can comprise a glass such as, for example, aluminosilicate, borosilicate, alumino-borosilicate, silica, and fused silica, that additionally optionally comprises one or more of the following: Al₂O₃, B₂O₃, MgO, CaO, SrO, BaO, SnO₂, Na₂O, K₂O, SrO, P₂O₃, ZrO₂, Li₂O, Ti, and/or Zn. In further examples of glass cores, the glass can comprise silicon and oxygen, as well as optionally any one or more of: aluminum, boron, magnesium, calcium, barium, tin, sodium, potassium, strontium, phosphorus, zirconium, lithium, titanium, and/or zinc. In some examples, a glass package substrate core comprises at least 23% silicon, at least 26% oxygen by weight. In further examples, the glass package substrate core comprises at least 23% silicon, at least 26% oxygen, and at least 5% aluminum by weight.

Additionally, examples of solid amorphous glass substrate cores can be considered to have a rectangular prism volume. The rectangular prism volume can contain vias that have been filled with one or more different materials. A material in a via can be a conductive metal such as copper. Examples of solid amorphous glass substrate cores can have a thickness in the range of 50 μm to 1.4 mm. Additionally, the package substrate can include a multi-layer glass substrate. The package substrate in this example may be a coreless substrate. The multi-layer glass substrate can have a thickness, for example, in the range of 25 μm to 50 μm. Further, glass substrate cores can have dimensions on a side of 10 mm to 250 mm. For example the substrate core can be 10 mm by 10 mm up to 250 mm by 250 mm in two dimensions, but substrate cores do not necessarily have to have the same value in both dimensions.

A package substrate can include one or more interconnect bridges. The interconnect bridge can be partially, fully, or not embedded into the package substrate. An interconnect bridge provides interconnects between chips that are housed on the package substrate. The interconnects can provide signal I/O between the chips. Some interconnect bridges, such as ones that have conductive through-bridge vias, can also provide power to an operably connected chip. The interconnect bridge can include regions having traces that have a smaller width dimension (the smallest dimension of the trace), a smaller height dimension, and/or a length dimension than the vias and traces of the surrounding package substrate. For example, width dimensions (or smallest dimension) can be 3 μm or less and/or 10 μm or less in some regions. The interconnect bridges can also have smaller trace spacings than the surrounding package substrate. For example, trace center-to-center spacings can be 3 μm and/or less or 10 μm or less in some regions. The interconnect bridge substrate can comprise, for example, silicon, silicon-on-insulator, float glass, borosilicate glass, silicon dioxide, polymeric, one or more organic polymeric materials, ceramic, and/or a silicon nitride material. The interconnect bridge substrate can comprise, for example, one or more dielectric layers that are comprise of, silicon oxides, silicon nitride, silicon oxynitride, carbon-doped oxide, methyl silsesquioxane, hydrogen silsesquioxane, die backside film (DBF), an epoxy film, a B-stage epoxy film, other dielectric material. The interconnect bridge can also include a coreless substrate comprised of a plurality of dielectric layers. The dielectric layers can be, for example, die backside film (DBF), an epoxy film, a B-stage epoxy film, or other dielectric material. Other materials are also possible for interconnect bridge substrates.

For packages that include interconnect bridges, the pitch in the interconnect bridge region for first level interconnects (FLIs) assemblies can be less than the pitch for other regions of the FLI assembly. The pitch in the interconnect bridge region for FLIs can be, for example, less than or equal to 25 μm.

Incorporating through-bridge vias (TBVs) into interconnect bridges can enable power to be routed from a substrate package cavity to a semiconductor chip attached to a package substrate. Through-bridge-vias can reduce the number of substrate routing layers required in a package substrate and can result in improved packaging yields. An interconnect bridge having TBVs can be for example, EMIB with TBVs, or EMIB-T. Depending on the bridge substrate material, a TBV may also be described as a through-silicon via (TSV) if the via traverses a region comprised of silicon, for example.

Enhanced electrical fault isolation capabilities during the manufacturing process can improve yield and reliability of semiconductor devices. Increases in interconnect and routing density add to yield, testing coverage, and defect resolution. Defects include shorts or resistive defects in the k Ω range (i.e., 100Ω to 5000Ω), hard shorts in the m Ω range (i.e., 100Ω and lower), and opens in the M Ω to G Ω range (i.e., 10000Ω and higher). The type of mode/technique selected can depend on the nature of the defect. For resistive defects, Joule heating of the defect can be imaged using a DC signal. While for opens (much higher resistance), the resistive heating can be less, so that impedance mismatch causing RF-losses that generate heat is used. There ca be some resistance range overlap between the shorts and open regime, where both the techniques can yield some results. Semiconductor devices can be semiconductor chips or semiconductor packages comprising semiconductor chips.

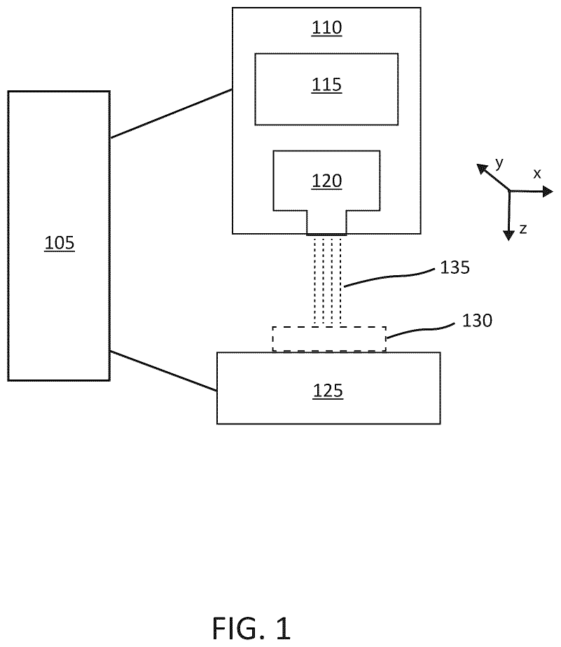

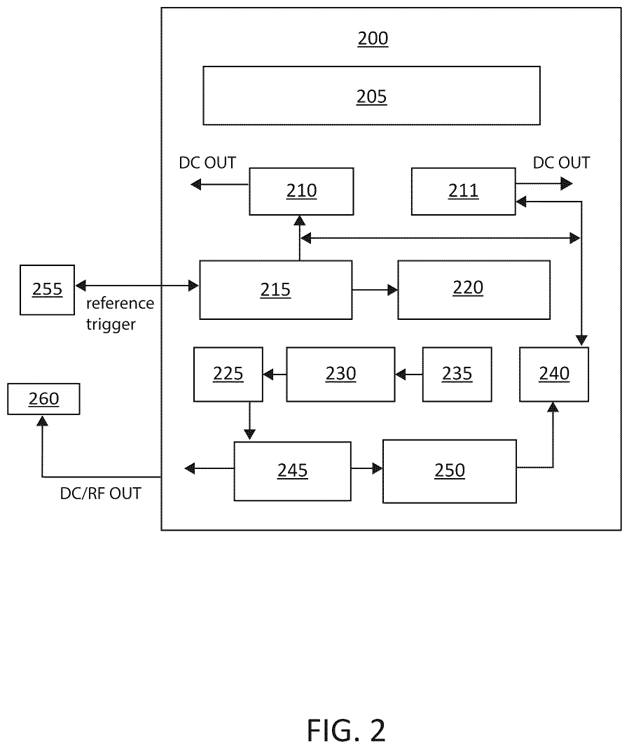

FIG. 1 provides a fault isolation system that can be useful for testing semiconductor devices. The fault isolation system includes a fault isolation module 105, an imaging module 110, and probing module 125 that, in operation, is capable of coupling to one or more devices under test (DUTs) 130. The fault isolation module 105 can be, for example, the fault isolation module of FIG. 2. The imaging module 110 includes a motorized unit 115 that is capable of translating a thermal imaging camera 120 in the x-y plane. The imaging module 110 is operably coupled to the fault isolation module 105 so that the thermal imaging camera 120 can be translated over the surface of a DUT 130. The dashed lines 135 represent the field of view of the thermal imaging camera 120. The imaging module 110 can, for example, be imaging module that can perform thermography, thermoreflectance, and/or other laser-based techniques. The fault isolation module 105 is also operably coupled to the probing module 125 and can couple to a DUT 130 through the probing module 125. The probing module 125 includes interconnects that can electrically couple to a DUT 130. Location of faults can be determined in the x, y, and z directions.

FIG. 2 illustrates a fault isolation module 200. The fault isolation module 200 can be used in the fault isolation system of FIG. 1. The fault isolation module 200 includes a power supply 205, a first source measurement unit 210 (SMU), a second source measurement unit 211, an arbitrary waveform generator 215 (AWG), a radio frequency (RF) signal generator and amplitude extender 220, a first RF multiplexer 225 (RF MUX), a RF amplifier 230, a second RF multiplexer 235, a computer controller 240, a RF coupler 245, and a RF power sensor 250. The first AWG 215 can be electrically coupled to an imaging module 255, such as the imaging module 110 of FIG. 1. The first AWG 215 provides a reference trigger to the imaging module 255. The fault isolation module 200 is an independent module that can be coupled with different imaging systems. The fault isolation module 200 can be operably coupled to a probing module 260 that is capable of coupling with a DUT (not shown).

By applying an amplified alternating high frequency electric field (radio frequency (RF) signal) across a failing semiconductor device structure, a thermal signature can be generated at selected locations. Locations of high impedance changes can be visualized for defect isolation. The excited circuit carrying the RF signal also emits a thermal signature (due to RF standing wave interaction) that can be used to visualize signal path. The first arbitrary waveform generator 215 generates a reference trigger to synchronize the external imaging system with the fault isolation module 200. The first arbitrary waveform generator 215 can also emit an in-sync (with the reference trigger) user-defined custom waveform that goes to the RF signal generator and amplitude extender 220 to generate in-phase RF signals (1 MHz to 10 GHz). A RF amplifier 230 can be used to further amplify the generated signal (up to 10 W). RF hardware components such as RF multiplexer 235, RF coupler 245, and RF power sensor 250 can be used to detect the RF power reflected from and reaching a device under test (DUT). Reflected power can be measured over range of frequencies, allowing a minimum reflected power to be selected so that RF power transmitted to DUT can be maximized.

The thermal energy dissipated (W) is directly related to the capacitance of the dielectric at the defect location, given by:

$$W = 2 π {E}^{2} fC η \times power factor$$

Where E represents voltage across a defect in a semiconductor device, f signifies frequency of the signal, C is the capacitance of the dielectric material at the defect location and η is the efficiency. Using a periodically modulated input signal, a fluctuation in surface temperature of the DUT is generated over the defect location, given by:

$$F ( t ) = A sin ( 2 π {f}_{s y n c} t + ϕ )$$

where A is the signal amplitude, f_{sync} is the synchronization frequency (1-100 Hz), t is the time and φ is the phase shift from the source location.

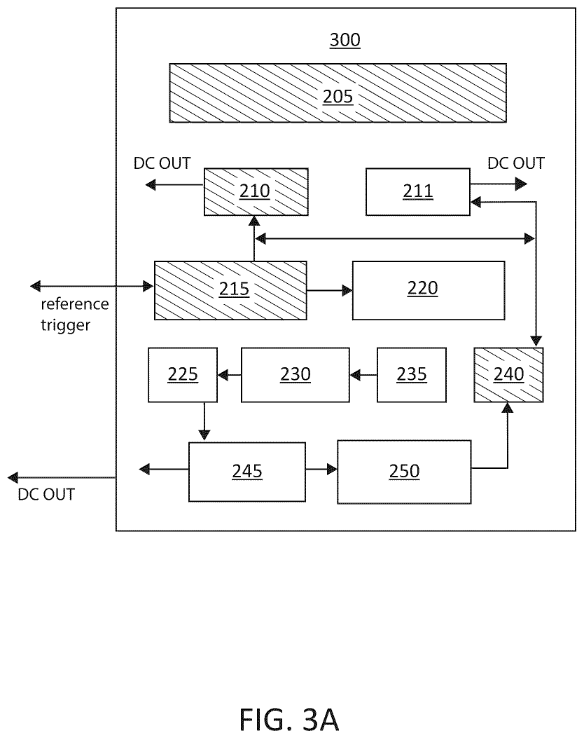

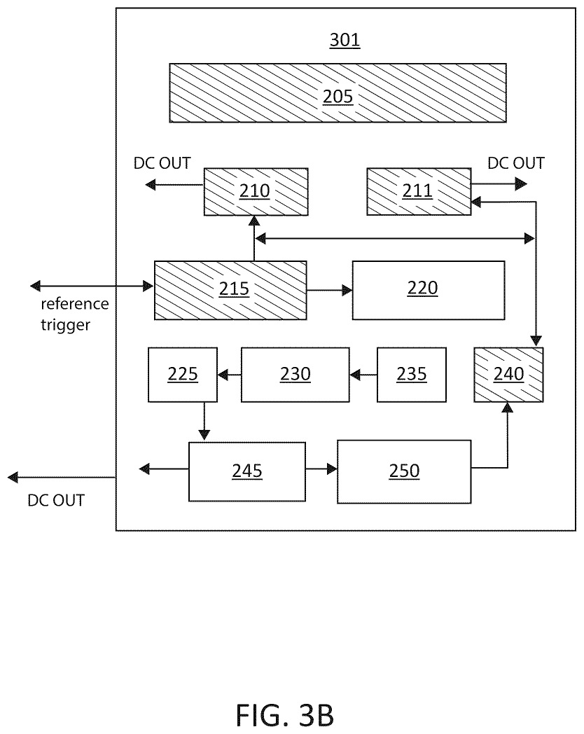

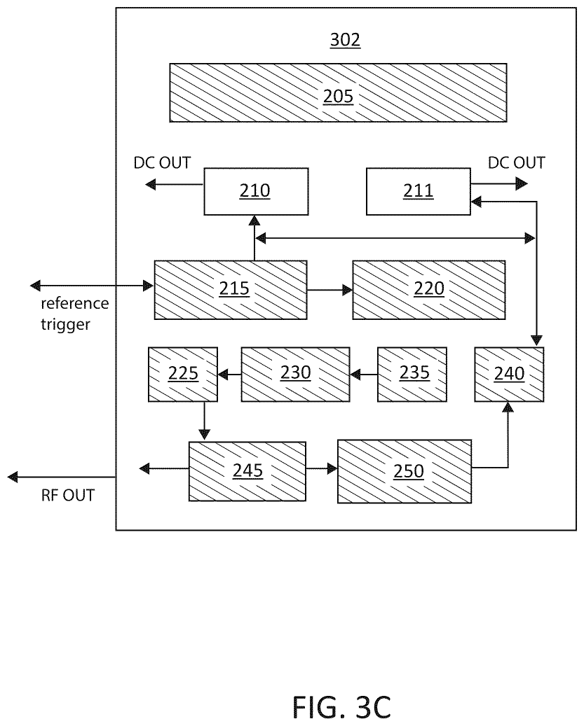

FIGS. 3A-3C illustrate a fault isolation module 300, 301, and 302 in use to detect electrical defects and faults in semiconductor devices. The fault isolation module can be the fault isolation module 200 of FIG. 2. Where the numbering is the same for FIG. 2 as in FIGS. 3A-3C, descriptions for those same-numbered parts in FIGS. 3A-3C from FIG. 2 can be used. Three modes of operation are illustrated in FIGS. 3A-3C in which modules that are active for fault detection are shown with diagonal striping. In FIG. 3A, the power supply 205, the first SMU 210, the AWG 215, and the computer controller 240 of the fault isolation module 300 are used for high resolution detection of electrical failures. FIG. 3A can be used to detect shorts and/or k Q resistive defects. In FIG. 3B, the power supply 205, the first and the second SMUs 210 and 211, the AWG 215, and the computer controller 240 of the fault isolation module 300 can be used for detection of hard shorts. In FIG. 3C, the power supply 205, the AWG 215, the RF signal generator and amplitude extender 220, the first RF MUX 225, the RF amplifier 230, the second RF MUX 235, and the computer controller 240 of the fault isolation module 300 can be used for detection of electrical opens. These modes of operation can cause electrical defects in semiconductor devices to light up for detection by a thermal imaging or laser-based imaging system.

For resistive defects and/or shorts, the SMUs 210 and 211 can be used to generate direct current (DC)/voltage, which can thermally excite the defect through joule heating (i.e., resistive heating). Similarly, the AWG 215 generates a reference trigger to synchronize the external imaging system with the SMUs 210 and 211 in fault isolation module. A single SMU 210 can be used for defects that exhibit a large resistance. When defects (hard shorts) have a very low resistance (compared to the rest of the circuit in series), a dual-source setup is used, as shown in FIG. 3B. Power emitted from functional resistors does not vary over time, but that of the defect does. This can create a distinct thermal signature belonging to defect, thereby allowing the defect to be thermally imaged.

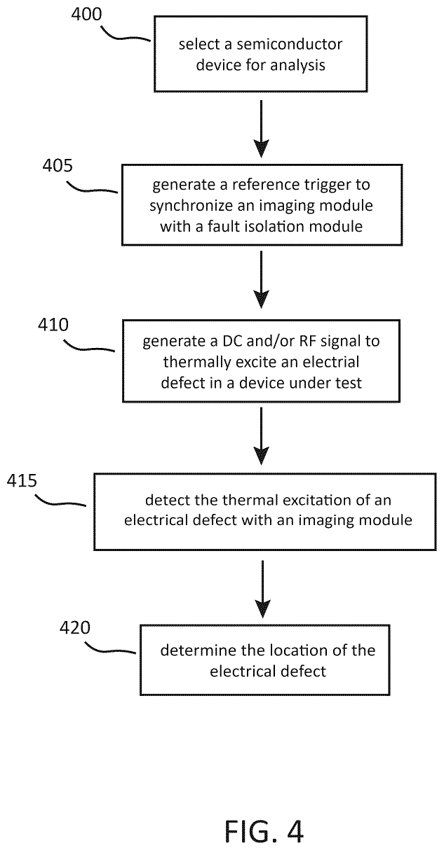

FIG. 4 provides a method for electrical fault isolation in a semiconductor device. The method of FIG. 4 can employ the systems described herein, such as, for example, the system of FIGS. 1 and 2 and FIGS. 3A-3C and include any of the operating details described herein for these systems. A semiconductor device is selected for analysis 400. A reference trigger is generated to synchronize an imaging module with a fault isolation module 405. A DC and/or RF signal is generated to thermally excite a defect in the selected semiconductor device (DUT) 410. The thermal excitation and/or signature of an electrical defect is detected using a thermal imaging module 415. The location of the electrical defect is determined 420. The depth of the electrical defect within the structure can also be determined. For example, the phase delay of the thermal signal can be measured. A thermal signal coming in from a deeper layer can have a larger phase delay and/or angle, than a thermal signal from a shallower layer. The RF frequency, power, and phase offset can be modulated for signal detection. For example, the radio frequency, reference trigger signal type, reference trigger frequency, phase difference/offset between reference trigger-RF signal and the RF power can be values that are chosen and/or optimized. The RF setup can be calibrated to only measure the power input to the DUT. The system can also sweep through a range of RF frequencies to identify the optimum frequency where minimum RF power is reflected from the DUT.

Semiconductor device substrates can be, for example, a silicon or silicon-on-insulator substate. Other materials for semiconductor substrates include, gallium arsenide, germanium, indium antimonide, lead telluride, indium phosphide, indium antimonide, indium gallium arsenide, or gallium antimonide. Other types of substrates are also possible and the devices described herein are not limited to a particular type of substrate.

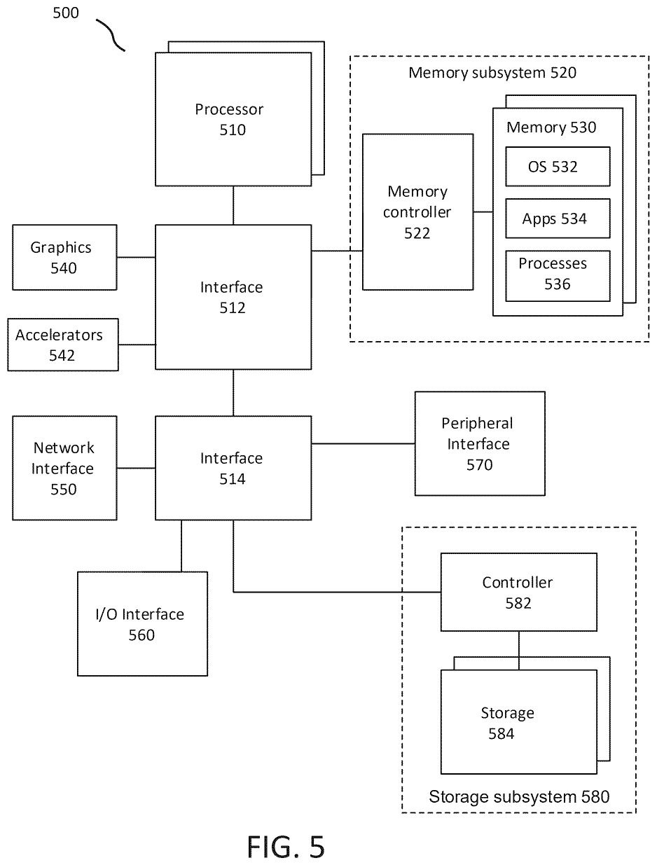

Semiconductor devices (or chips) can be any combination of microprocessors, CPUs (central processing units), GPUs (graphics processing units), processing cores, system on a chips, other processing hardware, a combination of processors or processing cores, programmable general-purpose or special-purpose microprocessors, accelerators, DSPs, I/O management, programmable controllers, ASICs, programmable logic devices (PLDs), HBM, and/or other memory devices. These semiconductor chip packages can be heterogeneous packages that incorporate different types of chips into one package. The semiconductor chips can be any of the chips, for example, described herein with respect to FIG. 5.

FIG. 5 depicts an example computing system. The computing system can be a system used for running equipment in a semiconductor fabrication plant. For example, instructions for performing one or more aspects of the process described herein can be stored and/or run on the computing system. A computing system 500 can include more, different, or fewer features than the ones described with respect to FIG. 5.

Computing system 500 includes processor 510, which provides processing, operation management, and execution of instructions for system 500. Processor 510 can include any type of microprocessor, CPU (central processing unit), GPU (graphics processing unit), processing core, or other processing hardware to provide processing for system 500, or a combination of processors or processing cores. Processor 510 controls the overall operation of system 500, and can be or include, one or more programmable general-purpose or special-purpose microprocessors, DSPs, programmable controllers, ASICs, programmable logic devices (PLDs), or the like, or a combination of such devices.

In one example, system 500 includes interface 512 coupled to processor 510, which can represent a higher speed interface or a high throughput interface for system components needing higher bandwidth connections, such as memory subsystem 520 or graphics interface components 540, and/or accelerators 542. Interface 512 represents an interface circuit, which can be a standalone component or integrated onto a processor die. Where present, graphics interface 540 interfaces to graphics components for providing a visual display to a user of system 500. In one example, the display can include a touchscreen display.

Accelerators 542 can be a fixed function or programmable offload engine that can be accessed or used by a processor 510. For example, an accelerator among accelerators 542 can provide data compression capability, cryptography services such as public key encryption (PKE), cipher, hash/authentication capabilities, decryption, or other capabilities or services. In some cases, accelerators 542 can be integrated into a CPU socket (e.g., a connector to a motherboard (or circuit board, printed circuit board, mainboard, system board, or logic board) that includes a CPU and provides an electrical interface with the CPU). For example, accelerators 542 can include a single or multi-core processor, graphics processing unit, logical execution unit single or multi-level cache, functional units usable to independently execute programs or threads, application specific integrated circuits (ASICs), neural network processors (NNPs), programmable control logic, and programmable processing elements such as field programmable gate arrays (FPGAs) or programmable logic devices (PLDs). Accelerators 542 can provide multiple neural networks, CPUs, processor cores, general purpose graphics processing units, or graphics processing units can be made available for use by artificial intelligence (AI) or machine learning (ML) models.

Memory subsystem 520 represents the main memory of system 500 and provides storage for code to be executed by processor 510, or data values to be used in executing a routine. Memory subsystem 520 can include one or more memory devices 530 such as read-only memory (ROM), flash memory, one or more varieties of random access memory (RAM) such as static RAM (SRAM), dynamic RAM (DRAM), synchronous DRAM (SDRAM) and/or or other memory devices, or a combination of such devices. Memory 530 stores and hosts, among other things, operating system (OS) 532 that provides a software platform for execution of instructions in system 500, and stores and hosts applications 534 and processes 536. In one example, memory subsystem 520 includes memory controller 522, which is a memory controller to generate and issue commands to memory 530. The memory controller 522 can be a physical part of processor 510 or a physical part of interface 512. For example, memory controller 522 can be an integrated memory controller, integrated onto a circuit within processor 510.

System 500 can also optionally include one or more buses or bus systems between devices, such memory buses, graphics buses, and/or interface buses. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a peripheral component interface (PCI) or PCI express (PCIe) bus, a Hyper Transport or industry standard architecture (ISA) bus, a small computer system interface (SCSI) bus, a universal serial bus (USB), or a Firewire bus.

In one example, system 500 includes interface 514, which can be coupled to interface 512. In one example, interface 514 represents an interface circuit, which can include standalone components and integrated circuitry. In one example, user interface components or peripheral components, or both, couple to interface 514. Network interface 550 provides system 500 the ability to communicate with remote devices (e.g., servers or other computing devices) over one or more networks. Network interface 550 can include an Ethernet adapter, wireless interconnection components, cellular network interconnection components, USB, or other wired or wireless standards-based or proprietary interfaces. Network interface 550 can transmit data to a device that is in the same data center or rack or a remote device, which can include sending data stored in memory.

Some examples of network interface 550 are part of an infrastructure processing unit (IPU) or data processing unit (DPU), or used by an IPU or DPU. An xPU can refer at least to an IPU, DPU, GPU, GPGPU (general purpose computing on graphics processing units), or other processing units (e.g., accelerator devices). An IPU or DPU can include a network interface with one or more programmable pipelines or fixed function processors to perform offload of operations that can have been performed by a CPU. The IPU or DPU can include one or more memory devices.

In one example, system 500 includes one or more input/output (I/O) interface(s) 560. I/O interface 560 can include one or more interface components through which a user interacts with system 500 (e.g., audio, alphanumeric, tactile/touch, or other interfacing). Peripheral interface 570 can include additional types of hardware interfaces, such as, for example, interfaces to semiconductor fabrication equipment and/or electrostatic charge management devices.

In one example, system 500 includes storage subsystem 580. Storage subsystem 580 includes storage device(s) 584, which can be or include any conventional medium for storing data in a nonvolatile manner, such as one or more magnetic, solid state, and/or optical based disks. Storage 584 can be generically considered to be a “memory,” although memory 530 is typically the executing or operating memory to provide instructions to processor 510. Whereas storage 584 is nonvolatile, memory 530 can include volatile memory (e.g., the value or state of the data is indeterminate if power is interrupted to system 500). In one example, storage subsystem 580 includes controller 582 to interface with storage 584. In one example controller 582 is a physical part of interface 512 or processor 510 or can include circuits or logic in both processor 510 and interface 514.

A power source (not depicted) provides power to the components of system 500. More specifically, power source typically interfaces to one or multiple power supplies in system 500 to provide power to the components of system 500.

Examples of systems may be implemented in various types of computing, smart phones, tablets, personal computers, and networking equipment, such as switches, routers, racks, and blade servers such as those employed in a data center and/or server farm environment.

A system can comprise: a first source measurement unit and a second source measurement unit; an arbitrary waveform generator coupled to the first source measurement unit and a second source measurement unit wherein the arbitrary waveform generator is capable of supplying a reference trigger to an imaging module; a radio frequency (RF) signal generator and amplitude extender wherein the RF signal generator and amplitude extender is coupled to the arbitrary waveform generator; a RF multiplexer coupled to the RF signal generator and amplitude extender; an RF coupler coupled to the RF multiplexer; and a RF power sensor coupled to the RF coupler. The RF coupler can be capable of supplying a RF signal to a device under test. The first source measurement unit can be capable of supplying a direct current (DC) signal to a device under test. The imaging module can be a thermal imaging module. The imaging module can be a laser-based imaging module. The system can also include a controller capable of directing a first operating mode of the system wherein the operating mode causes an electrical defect in a device under test to emit resistive heat. The system can also include a controller capable of directing a second operating mode of the system that causes an electrical defect in a device under test to emit a thermal signature.

A method can comprise: generating a reference trigger to synchronize a thermal imaging module with a fault isolation module; generating a direct current (DC) signal to thermally excite a first electrical defect in a device under test through resistive heating; detecting a thermal excitation of the first electrical defect in the device under test with the thermal imaging module; and determining a location of the first electrical defect in the device under test. The method can also include applying a radio frequency (RF) signal to generate a thermal signature in a second electrical defect in the device under test and detecting the thermal signature of the second electrical detect with the thermal imaging module. The RF signal can have a frequency between 1 MHz and 10 GHz. The method can also include measuring a RF power reflected from the device under test. The method can also include measuring a RF power reflected from the device under test over a range of frequencies and selecting a minimum reflected RF power. The thermal imaging module can be a laser-based imaging module. The reference trigger and the DC signal can be supplied by a source measurement unit.

At least one machine-readable storage medium can comprise non-transitory instructions, that when executed by a processor, cause a system comprising a fault isolation module and an imaging module to: generate reference trigger to synchronize a thermal imaging module with the fault isolation module; generate a direct current (DC) signal to thermally excite a first electrical defect in a device under test through resistive heating; detect a thermal excitation of the first electrical defect in the device under test with the imaging module; and determine a location of the electrical defect in the device under test. The non-transitory instructions can also include: apply a radio frequency (RF) signal to generate a thermal signature in a second electrical defect in the device under test and detecting the thermal signature of the second electrical defect with the imaging module. The RF signal can have a frequency between 1 MHz and 10 GHz. The non-transitory instructions can also include: measure a RF power reflected from the device under test. The non-transitory instructions can also include: measure a RF power reflected from the device under test over a range of frequencies and select a minimum reflected RF power. The thermal imaging module can be a laser-based imaging module.

Besides what is described herein, various modifications can be made to what is disclosed and implementations without departing from their scope. Therefore, the illustrations and examples herein should be construed in an illustrative, and not a restrictive sense.

What is claimed is:

1. A system comprising:
a first source measurement unit and a second source measurement unit;
an arbitrary waveform generator coupled to the first source measurement unit and a second source measurement unit wherein the arbitrary waveform generator is capable of supplying a reference trigger to an imaging module;
a radio frequency (RF) signal generator and amplitude extender wherein the RF signal generator and amplitude extender is coupled to the arbitrary waveform generator;
a RF multiplexer coupled to the RF signal generator and amplitude extender;
an RF coupler coupled to the RF multiplexer; and
a RF power sensor coupled to the RF coupler.

2. The system of claim 1 wherein the RF coupler is capable of supplying a RF signal to a device under test.

3. The system of claim 1 wherein the first source measurement unit is capable of supplying a direct current (DC) signal to a device under test.

4. The system of claim 1 wherein the imaging module is a thermal imaging module.

5. The system of claim 1 wherein the imaging module is a laser-based imaging module.

6. The system of claim 1 also including a controller capable of directing a first operating mode of the system wherein the operating mode causes an electrical defect in a device under test to emit resistive heat.

7. The system of claim 1 also including a controller capable of directing a second operating mode of the system that causes an electrical defect in a device under test to emit a thermal signature.

8. A method comprising:
generating a reference trigger to synchronize a thermal imaging module with a fault isolation module;
generating a direct current (DC) signal to thermally excite a first electrical defect in a device under test through resistive heating;
detecting a thermal excitation of the first electrical defect in the device under test with the thermal imaging module; and
determining a location of the first electrical defect in the device under test.

9. The method of claim 8 also including applying a radio frequency (RF) signal to generate a thermal signature in a second electrical defect in the device under test and detecting the thermal signature of the second electrical detect with the thermal imaging module.

10. The method of claim 9 wherein the RF signal has a frequency between 1 MHz and 10 GHz.

11. The method of claim 9 also including measuring a RF power reflected from the device under test.

12. The method of claim 9 also including measuring a RF power reflected from the device under test over a range of frequencies and selecting a minimum reflected RF power.

13. The method of claim 8 wherein the thermal imaging module is a laser-based imaging module.

14. The method of claim 8 wherein the reference trigger and the DC signal are supplied by a source measurement unit.

15. At least one machine-readable storage medium comprising non-transitory instructions, that when executed by a processor, cause a system comprising a fault isolation module and an imaging module to:
generate reference trigger to synchronize a thermal imaging module with the fault isolation module;
generate a direct current (DC) signal to thermally excite a first electrical defect in a device under test through resistive heating;
detect a thermal excitation of the first electrical defect in the device under test with the imaging module; and
determine a location of the electrical defect in the device under test.

16. The at least one machine-readable storage medium of claim 15 wherein the non-transitory instructions also include: apply a radio frequency (RF) signal to generate a thermal signature in a second electrical defect in the device under test and detecting the thermal signature of the second electrical defect with the imaging module.

17. The at least one machine-readable storage medium of claim 16 wherein the RF signal has a frequency between 1 MHz and 10 GHz.

18. The at least one machine-readable storage medium of claim 15 wherein the non-transitory instructions also include: measure a RF power reflected from the device under test.

19. The at least one machine-readable storage medium of claim 15 wherein the non-transitory instructions also include: measure a RF power reflected from the device under test over a range of frequencies and select a minimum reflected RF power.

20. The at least one machine-readable storage medium of claim 15 wherein the thermal imaging module is a laser-based imaging module.
